(19) United States
(12) Patent Application Publication
(10) Pub. No.: US 2025/0182808 A1
(43) Pub. Date: Jun. 5, 2025

(54) CONCURRENT ROW REFRESH AND ACTIVATE

(71) Applicant: Micron Technology, Inc., Boise, ID (US)

(72) Inventors: Martin Brox, München (DE); Erick Guerrero Rodriguez, Unterhaching (DE); Maksim Kuzmenka, München (DE); Filippo Vitale, Dachau (DE)

(21) Appl. No.: 18/949,663

(22) Filed: Nov. 15, 2024

Related U.S. Application Data
(60) Provisional application No. 63/605,943, filed on Dec. 4, 2023.

(51) Int. Cl. G11C 11/406

(52) U.S. Cl. CPC G11C 11/40615

(57) ABSTRACT

Methods, systems, and devices for concurrent row refresh and activate are described. Refreshing operations for memory cells may be performed concurrently with host-initiated access operations within a same bank of a memory system. For example, the memory system may receive a command to access a first row of a bank. The memory system may select a second row of the bank to refresh based on the second row being greater than a threshold distance away from the first row. The memory system may activate both the first row and the second row concurrently, thus performing a host-initiated access operation (on the first row) and a refresh operation (on the second row) concurrently. By doing so, the system may reduce a latency for host-initiated access operations while improving the reliability of the data.

### CROSS REFERENCE

The present Application for Patent claims priority to U.S. patent application Ser. No. 63/605,943 by Brox et al., entitled “CONCURRENT ROW REFRESH AND ACTIVATE,” filed Dec. 4, 2023, which is assigned to the assignee hereof, and which is expressly incorporated by reference in its entirety herein.

### TECHNICAL FIELD

The following relates to one or more systems for memory, including concurrent row refresh and activate.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports concurrent row refresh and activate in accordance with examples as disclosed herein.

FIG. 2 shows an example of a memory system that supports concurrent row refresh and activate in accordance with examples as disclosed herein.

FIG. 3 shows a block diagram of a memory system that supports concurrent row refresh and activate in accordance with examples as disclosed herein.

FIG. 4 shows a flowchart illustrating a method or methods that support concurrent row refresh and activate in accordance with examples as disclosed herein.

### DETAILED DESCRIPTION

Dynamic random-access memory (DRAM) architecture of memory cells is widely used in electronic devices. DRAM has a high performance (e.g., low latency) and a relatively low cost (as compared to other memory technologies). A memory cell of a DRAM device includes a capacitor that stores charge and a transistor to selectively couple the memory cell with sense components. The capacitor of a memory cell may leak charge over time, causing stored data to be lost. To prevent the loss of data due to charge leakage, memory cells may be recharged (or refreshed) periodically using a refresh operation. Periodic refresh operations may occur frequently enough to refresh all the memory cells of a memory system before the capacitors leak enough charge to lose their data or to make their data unreliable. A refresh operation may include reading data stored in a row of memory cells and then writing that data back into the row of memory cells. Refresh operations are background operations that may impact the performance of the memory system to perform host-initiated access operations (e.g., read operations, write operations). For example, when receiving a command to perform a host-initiated operation, the memory system may be busy performing refresh operations. The memory system may delay performing the host-initiated access operation and may generally have less time to perform host-initiated access operations when performing background operations, increasing latency for such operations.

As described herein, the system may support techniques for opportunistically refreshing memory cells concurrently with performing a host-initiated access operations within a same bank of a memory system. The memory system may receive a command to access a first row of a bank (e.g., as part of a reading or writing operation). The memory system may select a second row of the bank to refresh based on the second row being greater than a threshold distance away from the first row. The memory system may activate both the first row and the second row concurrently, thus performing a host-initiated access operation (on the first row) and a refresh operation (on the second row) concurrently. By performing a host-initiated access operation and a refresh operation at the same time, the system reduces latency for host-initiated access operations while ensuring the reliability of the data by continuing performing refresh operations.

In addition to applicability in memory systems described herein, techniques for concurrent row refresh and activate may be generally implemented to improve performance (e.g., decrease latency) and/or security (e.g., row hammer protections) features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by performing host commands more efficiently (e.g., more often and without waiting for refresh operations to finish), and may incur lower latency costs (e.g., by preforming host commands concurrently with refresh operations), among other benefits.

Features of the disclosure are illustrated and described in the context of systems and architectures. Features of the disclosure are further illustrated and described in the context of memory devices and flowcharts.

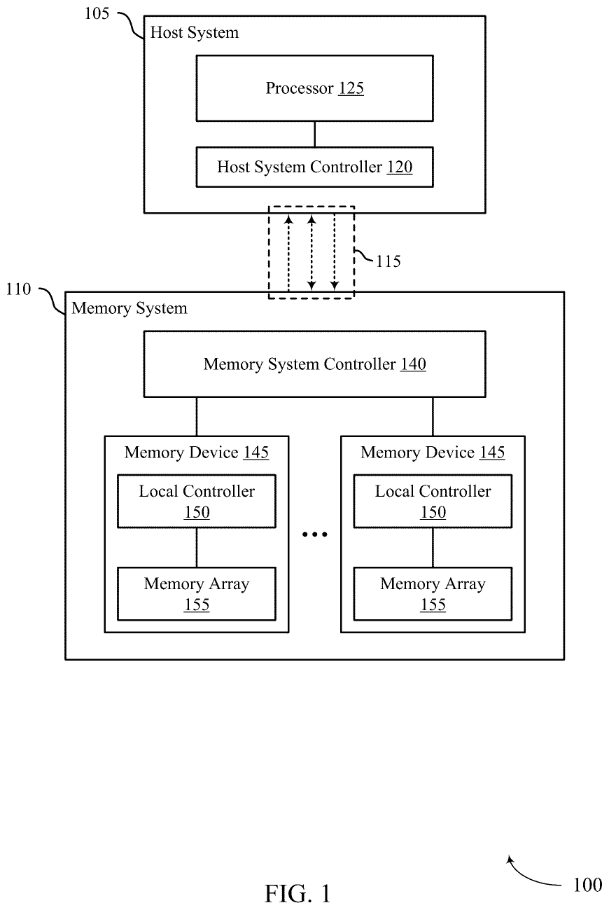

FIG. 1 illustrates an example of a system 100 that supports concurrent row refresh and activate in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

Memory cells (e.g., memory cells with DRAM architecture) may be recharged (or refreshed) periodically with a refresh operation to prevent data loss. A refresh operation may include reading data stored in a row of memory cells and then writing that data back into the row of memory cells. A refresh counter may keep track of which rows have been refreshed recently in a bank by using a row index. For example, a refresh counter may increment each time that a row is refreshed, such that a row index associated with the refresh counter increases by one. The incremented counter, or row index, indicates the next row to be refreshed in a next refresh operation. Refresh operations are background operations that may impact the performance of the memory system 110 to perform host-initiated access operations (e.g., read operations, write operations) from the host system 105. For example, when receiving a command to perform a host-initiated operation, the memory system 110 may be busy performing a refresh operation. The memory system 110 may delay performing the host-initiated operation and may generally have less time to perform host-initiated operations, increasing latency for such operations.

As described herein, the system 100 may support techniques for opportunistically refreshing memory cells concurrently with performing a host-initiated access operations (e.g., associated with a host-initiated command) within a same bank of a memory system 110. The memory system 110 may receive a command to access a first row of a bank (e.g., as part of a reading or writing operation). The memory system 110 may select a second row of the bank to refresh based on the second row being greater than a threshold distance away from the first row. Being greater than a threshold distance away from the first row may refer to the second row being far enough away from the first row that the second row does not share sense components with the first row. In other words, the sense components associate with the first row are independent from the sense component associated with the second row. The memory system 110 may activate both the first row and the second row concurrently, thus performing a host-initiated access operation (on the first row) and a refresh operation (on the second row) concurrently. By performing a host-initiated access operation and a refresh operation at the same time, the system 100 reduces latency for host-initiated access operations while ensuring the reliability of the data by continuing to perform refresh operations.

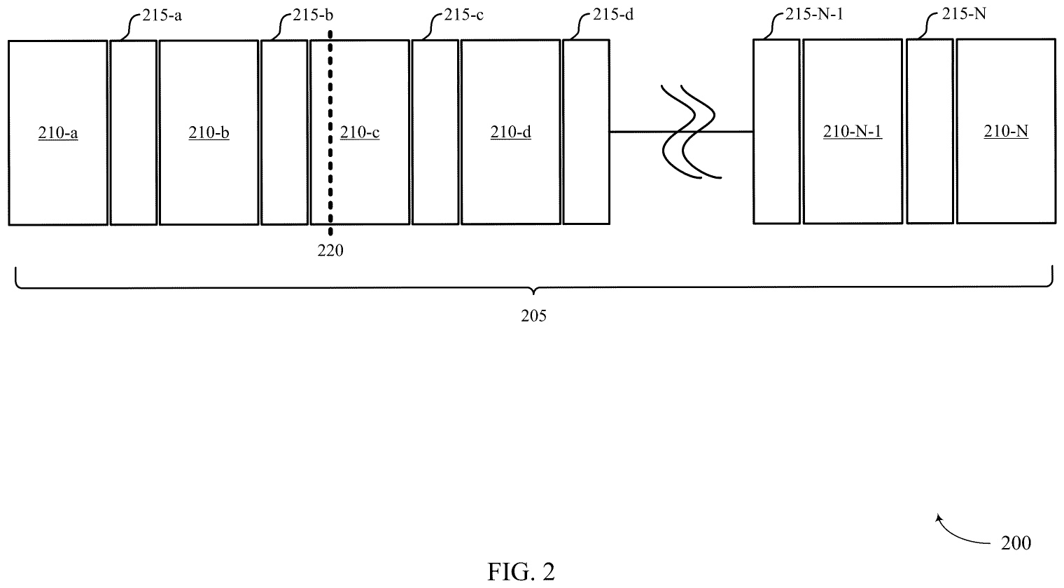

FIG. 2 shows an example of a memory system 200 that supports concurrent row refresh and activate in accordance with examples as disclosed herein. The memory system 200 may be implemented at a system 100, or implement aspects of a system 100, as described with reference to FIG. 1. The memory system 200 may include a bank 205. The bank 205 (of memory cells) may be implemented in a memory system 110, a memory die 160, or a memory array 155. The bank 205 may be made up of bank segments 210 (e.g., 201-a, 210-b, 210-c, 210-d. . . 210-N-1, 210-N where N indicates the quantity of bank segments 210). Each bank segment 210 contains rows and columns that can be activated to access memory cells. Row 220 is an example of a row that is activated. The bank 205 may also include sense components 215 (e.g., 215-a, 215-b, 215-c, 215-d, . . . 215-N-1, 215-N where N indicates the quantity of sense components 215, which may be the same as the quantity of bank segments 210). Each sense component 215 may be coupled with the bank segments 210 adjacent to (e.g., on either side) of them. The bank 205 may be configured to support concurrent access of memory cells to host-initiated access operations and refresh operations, which may decrease latency associated with accessing the bank 205 while maintaining reliable data.

The memory system 200 may have any quantity of banks (e.g., 8, 16, 32 banks), although only bank 205 is shown. The bank 205 may contain any quantity of bank segments 210. Each bank segment 210 may be associated with a decoder that is independent from the decoders of other bank segments 210 and/or a set of sense components that are independent from other bank segments. Each bank segment 210 may contain any quantity of rows. One or more rows of the bank 205 may be activated as a result of a host command (e.g., a read or write command) or as part of a refresh operation. Row activation may include moving charge from a capacitor associated with a memory cell into a sense component 215 for each memory cell in the row. For a given row being accessed, the sense components 215 on either side of the bank segment 210 associated with the row being accessed may be activated. For example, if row 220 in bank segment 210-c is activated, then the sense components 215-b and 215-c may be activated. The sense components 215 may be sense amplifiers that amplify signals from the associated activated memory cells to recognizable logic levels, allowing the data to be interpreted properly.

Multiple rows may be accessed at a same time, as long as their associated sense components 215 do not overlap. Sense components 215 may be configured to interact with multiple bank segments (e.g., a bank segment on either side of the sense components). In such cases, multiple rows may be activated at the same time as long as the rows are far enough away (greater than a threshold distance) from each other. For example, if row 220 in bank segment 210-c is being activated, then sense components 215-b and 215-c may be activated. This may block neighboring bank segments 210-b and 210-d from being activated because each sense component may be limited to holding charge associated with one bank segment 210 at a time. In this example, the sense component 215-b stores charges associated with bank segment 210-c and may not, at the same time, be able to store charges associated with bank segment 210-b. Similarly, the sense component 215-c stores charges associated with bank segment 210-c and may not, at the same time, be able to store charges associated with bank segment 210-d. Accordingly, rows in bank segments 210-b and in bank segment 210-d may not be activated while rows in bank segment 210-c are activated. However, rows in bank segments 210-a, 210-N-1, 210-N and other bank segments 210 not shown may not share sense components 215 (e.g., sense components 215-b and 215-c) with bank segment 210-c and may be accessed simultaneously with rows in bank segment 210-c.

Because multiple rows in the bank 205 may be accessed at one time, the memory system 200 may be able to perform host-initiated access operations concurrently with refresh operations, as long as the host-initiated access operations and the refresh operations do not access the same or neighboring bank segments 210. In some examples, alternating (e.g., every other) bank segment 210 may be accessed concurrently (e.g., bank segment 210-a, 210-c, . . . 210-N).

In some memory systems, refresh operations may follow a linear pattern using a refresh counter. For example, the memory system 200 may refresh row 0, then row 1, then row 2, then row 3, etc. according to a row index until all rows in the bank 205 are refreshed within a time period. Then the memory device may perform another set of refresh operations after the time period, restarting at row 0 and refreshing all the rows of the bank 205. The memory system 200 may keep track of which rows have been refreshed and which row to refresh next via a refresh counter (in combination with the linear pattern). Sometimes timings for refreshing all rows in a bank are set so that the data stored in the bank does not degrade too much before the next refresh occurs.

The bank segment 210 and row that a host-initiated access operation requests to access may be unpredictable. The unpredictable nature of the host-initiated access operation may interfere with the linear pattern of refreshing rows with a single refresh counter. For example, if the host requests access to row 220, then the memory system 200 may not be able to perform a refresh on any row in bank segment 210-c, or bank segments 210-b and 210-d, concurrent with the host request. The bank segments 210 that may not be able to be refreshed due to the host request may be collectively called a blocked region. In this example, bank segments 210-b, 210-c, and 210-d may be a blocked region. The bank segments 210 that may be accessed (e.g., via a refresh operation) while a row is accessed due to a host request may be collectively called an unblocked region. In other words, portions of the bank 205 that are not part of the blocked region may be part of the unblocked region. In this example, bank segments 210 that are not bank segments 210-b, 210-c, and 210-d may be an unblocked region (e.g., the unblocked region includes bank segments 210-a, 210-N-1, 210-N and other bank segments not shown). In other words, the unblocked region may include bank segments 210 that are at least a threshold distance (e.g., at least one bank segment 210 away) from the host-activated row. Performing refresh operations concurrently with host-initiated access operation may create situations where refresh operations are blocked. Techniques are described herein to perform refresh operations concurrently with host-initiated access operations and address situations where blocking of refresh operations may occur.

In some examples, the memory system 200 may receive a command to access (e.g., a host-initiated access operation) a row (e.g., row 220) of the bank 205 of the memory system 200. The memory system 200 may check the refresh counter to determine whether the next refresh operation is to be performed in a blocked region of the bank 205 (e.g., a region of the memory bank that is blocked due to the access operation, in this example, bank segments 210-b through 210-d), or whether the next refresh operation is to be performed in an unblocked region of the bank 205 (the other bank segments 210, a threshold distance from activated segment 210-c, not all of which are shown). If the next refresh operation is slated to occur in the unblocked region of the bank 205, then the refresh may proceed according to the refresh counter, such that the host-initiated access operation and the refresh occur concurrently. The respective rows accessed by the host-initiated access operation and the refresh operation may be accessed by activating the rows to transfer charge from memory cells associated with the rows to respective sense components 215.

If the next refresh operation is slated to occur in the blocked region of the bank 205, then the memory system 200 may determine a row in a different bank segment 210 to refresh instead, such that the host-initiated access operation and the refresh may occur concurrently. The row to refresh may be determined based on the row being at least a threshold distance away from the row that is being accessed (e.g., row 220) due to the host-initiated access operation (e.g., the row is not in, or next to, the bank segment 210-c). In other words, the refresh operation may refrain from continuing with the linear progression of rows, instead refreshing a discontinuous row. After the host-initiated access operation, a subsequent refresh operation may resume where the refresh counter left off. Once the linear refresh counter reaches the row that was refreshed concurrently with the host-initiated access operation, the memory system 200 may skip that row (e.g., refrain from refreshing that row), that row already having been refreshed within the relevant duration.

In some examples, flags (e.g., logic 0 or 1) may be used to indicate which rows have been refreshed recently. In some examples, a flag may be set to indicate which row was refreshed out of order (e.g., when breaking the linear order of the refresh counter due to the host access operation). In some examples, each row may be associated with a flag that indicates whether the row has been refreshed. Once the refresh counter reaches the row associated with the one or more flags indicating that the row was previously refreshed within a certain duration, then the memory system 200 may skip the refresh of that row. After all the rows have been refreshed, the one or more flags may be reset. Additionally or alternatively, the one or more flags may be reset after a period of time associated with refreshing rows to prevent data loss.

In some examples, repeated host-initiated access operations that access the same bank segment 210, may cause data loss by preventing (e.g., disrupting) refresh operations in the corresponding bank segment 210. To avoid data loss, the memory system 200 may alternate or interleave between two types of refresh operations. A first type of refresh operations, which may be referred to as hidden refresh operations or non-blocking refresh operations, may include refreshing rows while concurrently performing host-initiated access operations. A second type of refresh operations, which may be referred to as dedicated refresh operations or blocking refresh operations, may include performing refresh operations while blocking or delaying host-initiated access operations. In other words, dedicated refresh operations may occur independently from any host access operations. The memory system 200 may perform a set of hidden refreshes for a first time period. The first time period may be associated with the duration in which every memory cell in the bank 205 is refreshed to prevent data loss (e.g., in accordance with manufacturing standards). Then, for a second time period, the memory system 200 may perform a set of dedicated refreshes to ensure that each row is refreshed within a time period. The second time period may be associated with a duration in which the memory system 200 refreshes every memory cell of the bank 205. Interleaving hidden refreshes and blocking refreshes may allow some refresh operations to be done concurrently with host-initiated access operations and mitigate risks from host-initiated access operation from blocking the refresh of rows for too extended of periods of time.

The memory system 200 may alternate between, or interleave, sets of hidden refreshes and sets of dedicated refreshes such that every other set of refreshes is a dedicated refresh, every third set of refreshes is a dedicated refresh, every nth set of refreshes is a dedicated refresh, or some other arrangement, not necessarily following a strict pattern. In some examples, the hidden refresh operations and the dedicated refresh operations each have separate refresh counters. The two refresh counters may each follow a linear pattern.

In some examples, the memory system 200 may use a plurality of refresh counters to perform hidden refreshes and mitigate issues with blocking by host-initiated access operations. In some examples, the refresh operations may be associated with two (Or more) refresh counters. For example, a first refresh counter may be associated with a first portion of the bank 205 (e.g., banks segment 210-a through 210-N/2 where N/2 corresponds to a half the quantity of bank segments 210 in the bank 205). A second refresh counter may be associated with a second portion of the bank 205 (e.g., the bank segments 210 not in the first portion of the bank 205). The memory system 200 may determine whether to perform a refresh operation using the first refresh counter or according to the second refresh counter based on the row that the host access operation is accessing.

For example, if the host access operation corresponds to row 220, and the first refresh counter corresponds to a row in a bank segment 210 that corresponds to a blocked region of the bank 205 (e.g., a bank segment 210 within a threshold distance of bank segment 210-c), then the memory system 200 may perform a refresh operation according to the second refresh counter that may correspond to an unblocked region of the bank 205 (e.g., a bank segment outside of a threshold distance of bank segment 210-c, such as bank segment 210-N-1). The memory system 200 may then increment the second refresh counter (e.g., increment a row index associated with the second hidden refresh counter). The memory system 200 may return to performing refresh operations according to the first refresh timer or may continue to refresh according to the second refresh counter for a threshold amount of time, for a threshold amount of refresh operations, until all rows in the corresponding portion of the bank 205 have been refreshed, or until a second host access operation interferes with the hidden refresh operations of the second portion of the bank 205.

In some examples, the first and second refresh counters may be set up such that their respective rows are at least a threshold distance away from each other to prevent both from corresponding to rows within a threshold distance of a given host access operation. In other words, regardless of where the host access operation requests to activate, at least one of the two refresh counters may refer to a bank segment 210 far enough away from the host-activated row that refresh may be performed according to that refresh counter concurrently with the host access operation without interference.

In some examples, the refresh operations may be associated with any quantity of refresh counters. The refresh counters may be associated with different portions of the bank 205. For example, if there are three refresh counters, each refresh counter may be associated with approximately one third of the bank segments 210 (each third nonoverlapping) of the bank 205. If there are four refresh counters, each refresh counter may be associated with approximately one fourth of the bank segments 210 of the bank 205, etc. The memory system 200, similarly to the examples of the memory system 200 with two refresh counters described herein, may rotate, alternate, or switch between refresh counters based on where a host access operation activates. Multiple refresh counters may allow refresh operations to be concurrent with host-initiated access operations without overlapping use of sense components 215.

Coordinating refresh operations and host-initiated access operations may allow the memory system 200 to be more efficient. For example, concurrent refresh operations and host access operations may reduce latency for host access operations, since the memory system 200 may perform the access operations sooner and more often than if the memory system 200 waited for refresh operations to be complete. The techniques described herein of concurrent row refresh operations and row activates relating to host-initiated access operations also maintain data reliability in DRAM devices.

Different techniques for performing hidden refresh operations may be used in different combinations. Examples of such techniques may include (but are not limited to) opportunistically performing hidden refresh operations (e.g., if the row indicated by the refresh counter is blocked, then skip that hidden refresh), using one or more flags to track whether random rows have been refreshed and then skipping refreshing those rows when a refresh counter gets to the row, interleaving blocking refreshes and hidden refreshes, and maintain multiple refresh counters. Any combination of techniques may be used to perform refresh operations. In some examples, interleaving blocking refreshes and hidden refreshes may be used in combination with using a plurality of refresh counters. In some examples, interleaving blocking refreshes and hidden refreshes may be used in combination with using flags to track random rows that have been refreshed. In some examples, interleaving blocking refreshes and hidden refreshes may be used in combination with using opportunistically performing hidden refreshes. Other combinations of techniques may also be employed.

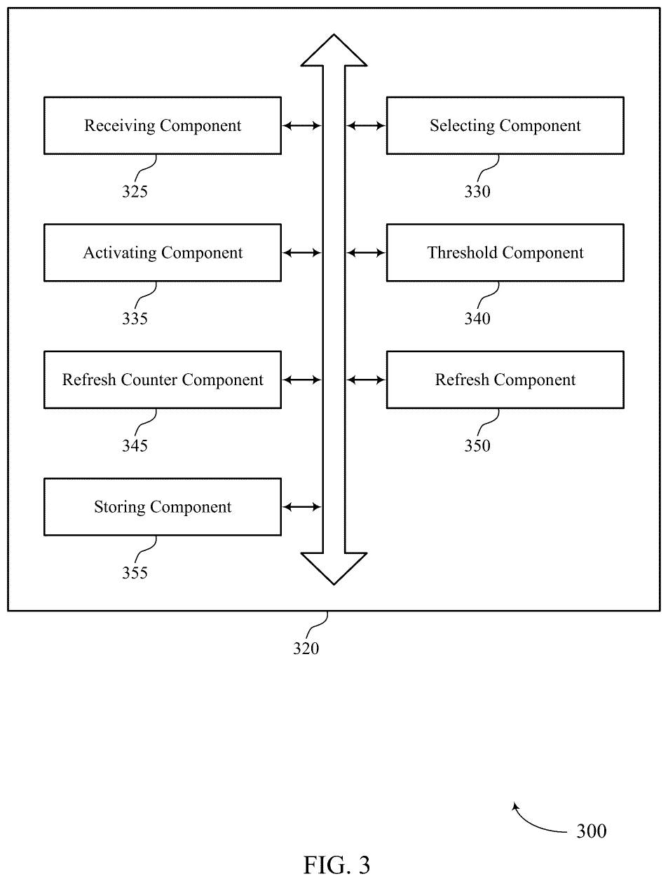

FIG. 3 shows a block diagram 300 of a memory system 320 that supports concurrent row refresh and activate in accordance with examples as disclosed herein. The memory system 320 may be an example of aspects of a memory system as described with reference to FIGS. 1 through 2. The memory system 320, or various components thereof, may be an example of means for performing various aspects of concurrent row refresh and activate as described herein. For example, the memory system 320 may include a receiving component 325, a selecting component 330, an activating component 335, a threshold component 340, a refresh counter component 345, a refresh component 350, a storing component 355, or any combination thereof. Each of these components, or components of subcomponents thereof (e.g., one or more processors, one or more memories), may communicate, directly or indirectly, with one another (e.g., via one or more buses).

The receiving component 325 may be configured as or otherwise support a means for receiving a command to access a first row of a bank of the memory system. The selecting component 330 may be configured as or otherwise support a means for selecting a second row of the bank to refresh concurrently with activating the first row of the bank based at least in part on receiving the command. The activating component 335 may be configured as or otherwise support a means for activating the first row of the bank to transfer charge from a first memory cell to a first sense component of the memory system as part of a host-initiated access operation based at least in part on the command. In some examples, the activating component 335 may be configured as or otherwise support a means for activating the second row of the bank to transfer charge from a second memory cell to a second sense component concurrently with activating the first row as part of a refresh operation based at least in part on selecting the second row.

In some examples, to support selecting the second row, the threshold component 340 may be configured as or otherwise support a means for determining that the second row is at least a threshold distance away from the first row.

In some examples, the refresh counter component 345 may be configured as or otherwise support a means for determining a first row index indicated by a refresh counter associated with the bank. In some examples, the threshold component 340 may be configured as or otherwise support a means for determining that the first row index is at least a threshold distance away from a second row index of the first row, where the second row is selected based at least in part on the first row index being at least the threshold distance away from the second row index of the first row.

In some examples, the refresh counter component 345 may be configured as or otherwise support a means for determining a first row index indicated by a refresh counter associated with the bank. In some examples, the threshold component 340 may be configured as or otherwise support a means for determining that the first row index is less than a threshold distance away from a second row index of the first row. In some examples, the threshold component 340 may be configured as or otherwise support a means for determining a third row index that is greater than the threshold distance away from the second row index of the first row, where the second row is selected based at least in part on the third row index being at least the threshold distance away from the first row index of the first row.

In some examples, the refresh counter component 345 may be configured as or otherwise support a means for determining a third row to refresh using a refresh counter associated with the bank after activating the second row. In some examples, the activating component 335 may be configured as or otherwise support a means for activating the third row of the bank without activating any other row to refresh the third row.

In some examples, a first set of refresh operations occur concurrently with host-initiated access operations and a second set of refresh operations occur independently from performing host-initiated access operations.

In some examples, the memory system attempts refresh operations according to a pattern that interleaves a first set of refresh operations that occur concurrently with host-initiated access operations and a second set of refresh operations that occur independently from performing host-initiated access operations.

In some examples, the refresh counter component 345 may be configured as or otherwise support a means for determining a first row index indicated by a first refresh counter associated with the bank. In some examples, the refresh counter component 345 may be configured as or otherwise support a means for determining a second row index indicated by a second refresh counter associated with the bank. In some examples, the refresh component 350 may be configured as or otherwise support a means for determining whether to use the first row index or the second row index as the second row refreshed by the refresh operation, where activating the second row is based at least in part on determining whether to use (e.g., the determining of whether to use) the first row index or the second row index.

In some examples, to support determining whether to use the first row index or the second row index, the threshold component 340 may be configured as or otherwise support a means for determining whether the first row index is less than a threshold distance away from a row index associated with the first row.

In some examples, the bank includes a quantity of refresh counters, each refresh counter of the quantity to refresh counters associated with a different portion of the bank.

In some examples, the storing component 355 may be configured as or otherwise support a means for storing an indicator that the second row was refreshed within a duration based at least in part on activating the second row. In some examples, the refresh counter component 345 may be configured as or otherwise support a means for determining that a row index indicated by a refresh counter associated with the bank is associated with the second row. In some examples, the refresh component 350 may be configured as or otherwise support a means for skipping refreshing the second row based at least in part on the indicator for the second row being stored.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

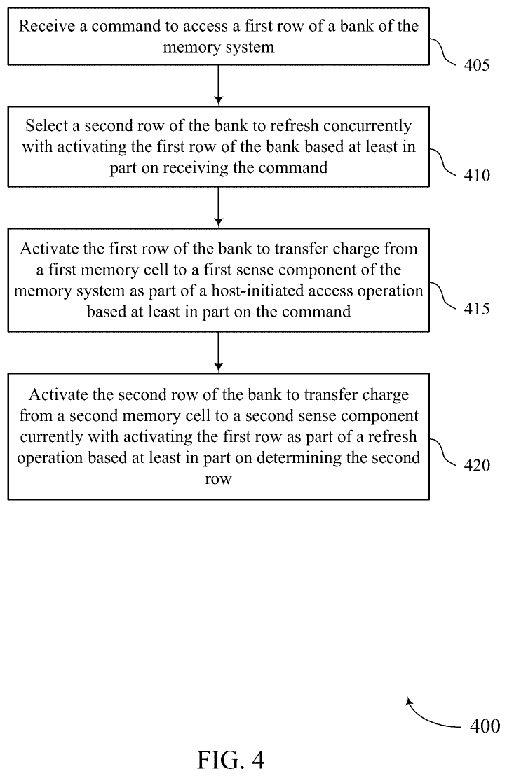

FIG. 4 shows a flowchart illustrating a method 400 that supports concurrent row refresh and activate in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the system to perform the described functions. Additionally, or alternatively, the memory system may perform aspects of the described functions using special-purpose hardware.

At 405, the method may include receiving a command to access a first row of a bank of the memory system. In some examples, aspects of the operations of 405 may be performed by a receiving component 325 as described with reference to FIG. 3.

At 410, the method may include selecting a second row of the bank to refresh concurrently with activating the first row of the bank based at least in part on receiving the command. In some examples, aspects of the operations of 410 may be performed by a selecting component 330 as described with reference to FIG. 3.

At 415, the method may include activating the first row of the bank to transfer charge from a first memory cell to a first sense component of the memory system as part of a host-initiated access operation based at least in part on the command. In some examples, aspects of the operations of 415 may be performed by an activating component 335 as described with reference to FIG. 3.

At 420, the method may include activating the second row of the bank to transfer charge from a second memory cell to a second sense component concurrently with activating the first row as part of a refresh operation based at least in part on selecting the second row. In some examples, aspects of the operations of 420 may be performed by an activating component 335 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a command to access a first row of a bank of the memory system; selecting a second row of the bank to refresh concurrently with activating the first row of the bank based at least in part on receiving the command; activating the first row of the bank to transfer charge from a first memory cell to a first sense component of the memory system as part of a host-initiated access operation based at least in part on the command; and activating the second row of the bank to transfer charge from a second memory cell to a second sense component concurrently with activating the first row as part of a refresh operation based at least in part on selecting the second row.

Aspect 2: The method, apparatus, or non-transitory computer-readable medium of aspect 1, where selecting the second row includes operations, features, circuitry, logic, means, or instructions, or any combination thereof for determining that the second row is at least a threshold distance away from the first row.

Aspect 3: The method, apparatus, or non-transitory computer-readable medium of any of aspects 1 through 2, further including operations, features, circuitry, logic, means, or instructions, or any combination thereof for determining a first row index indicated by a refresh counter associated with the bank and determining that the first row index is at least a threshold distance away from a second row index of the first row, where the second row is selected based at least in part on the first row index being at least the threshold distance away from the second row index of the first row.

Aspect 4: The method, apparatus, or non-transitory computer-readable medium of any of aspects 1 through 2, further including operations, features, circuitry, logic, means, or instructions, or any combination thereof for determining a first row index indicated by a refresh counter associated with the bank; determining that the first row index is less than a threshold distance away from a second row index of the first row; and determining a third row index that is greater than the threshold distance away from the second row index of the first row, where the second row is selected based at least in part on the third row index being at least the threshold distance away from the first row index of the first row.

Aspect 5: The method, apparatus, or non-transitory computer-readable medium of any of aspects 1 through 4, further including operations, features, circuitry, logic, means, or instructions, or any combination thereof for determining a third row to refresh using a refresh counter associated with the bank after activating the second row and activating the third row of the bank without activating any other row to refresh the third row.

Aspect 6: The method, apparatus, or non-transitory computer-readable medium of any of aspects 1 through 5, where a first set of refresh operations occur concurrently with host-initiated access operations and a second set of refresh operations occur independently from performing host-initiated access operations.

Aspect 7: The method, apparatus, or non-transitory computer-readable medium of any of aspects 1 through 6, where the memory system attempts refresh operations according to a pattern that interleaves a first set of refresh operations that occur concurrently with host-initiated access operations and a second set of refresh operations that occur independently from performing host-initiated access operations.

Aspect 8: The method, apparatus, or non-transitory computer-readable medium of any of aspects 1 through 7, further including operations, features, circuitry, logic, means, or instructions, or any combination thereof for determining a first row index indicated by a first refresh counter associated with the bank; determining a second row index indicated by a second refresh counter associated with the bank; and determining whether to use the first row index or the second row index as the second row refreshed by the refresh operation, where activating the second row is based at least in part on determining whether to use (e.g., the determining of whether to use) the first row index or the second row index.

Aspect 9: The method, apparatus, or non-transitory computer-readable medium of aspect 8, where determining whether to use the first row index or the second row index includes operations, features, circuitry, logic, means, or instructions, or any combination thereof for determining whether the first row index is less than a threshold distance away from a row index associated with the first row.

Aspect 10: The method, apparatus, or non-transitory computer-readable medium of any of aspects 1 through 9, where the bank includes a quantity of refresh counters, each refresh counter of the quantity to refresh counters associated with a different portion of the bank.

Aspect 11: The method, apparatus, or non-transitory computer-readable medium of any of aspects 1 through 10, further including operations, features, circuitry, logic, means, or instructions, or any combination thereof for storing an indicator that the second row was refreshed within a duration based at least in part on activating the second row; determining that a row index indicated by a refresh counter associated with the bank is associated with the second row; and skipping refreshing the second row based at least in part on the indicator for the second row being stored.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method by a memory system, comprising:
receiving a command to access a first row of a bank of the memory system;
selecting a second row of the bank to refresh concurrently with activating the first row of the bank based at least in part on receiving the command;
activating the first row of the bank to transfer charge from a first memory cell to a first sense component of the memory system as part of a host-initiated access operation based at least in part on the command; and
activating the second row of the bank to transfer charge from a second memory cell to a second sense component concurrently with activating the first row as part of a refresh operation based at least in part on selecting the second row.

2. The method of claim 1, wherein selecting the second row comprises:
determining that the second row is at least a threshold distance away from the first row.

3. The method of claim 1, further comprising:
determining a first row index indicated by a refresh counter associated with the bank; and
determining that the first row index is at least a threshold distance away from a second row index of the first row, wherein the second row is selected based at least in part on the first row index being at least the threshold distance away from the second row index of the first row.

4. The method of claim 1, further comprising:
determining a first row index indicated by a refresh counter associated with the bank;
determining that the first row index is less than a threshold distance away from a second row index of the first row; and
determining a third row index that is greater than the threshold distance away from the second row index of the first row, wherein the second row is selected based at least in part on the third row index being at least the threshold distance away from the first row index of the first row.

5. The method of claim 1, further comprising:
determining a third row to refresh using a refresh counter associated with the bank after activating the second row; and
activating the third row of the bank without activating any other row to refresh the third row.

6. The method of claim 1, wherein a first set of refresh operations occur concurrently with host-initiated access operations and a second set of refresh operations occur independently from performing host-initiated access operations.

7. The method of claim 1, wherein the memory system attempts refresh operations according to a pattern that interleaves a first set of refresh operations that occur concurrently with host-initiated access operations and a second set of refresh operations that occur independently from performing host-initiated access operations.

8. The method of claim 1, further comprising:
determining a first row index indicated by a first refresh counter associated with the bank;
determining a second row index indicated by a second refresh counter associated with the bank; and
determining whether to use the first row index or the second row index as the second row refreshed by the refresh operation, wherein activating the second row is based at least in part on determining whether to use the first row index or the second row index.

9. The method of claim 8, wherein determining whether to use the first row index or the second row index comprises:
determining whether the first row index is less than a threshold distance away from a row index associated with the first row.

10. The method of claim 1, wherein the bank includes a quantity of refresh counters, each refresh counter of the quantity to refresh counters associated with a different portion of the bank.

11. The method of claim 1, further comprising:
storing an indicator that the second row was refreshed within a duration based at least in part on activating the second row;
determining that a row index indicated by a refresh counter associated with the bank is associated with the second row; and
skipping refreshing the second row based at least in part on the indicator for the second row being stored.

12. A memory system, comprising:
one or more memory devices; and
processing circuitry coupled with the one or more memory devices and configured to cause the memory system to:
receive a command to access a first row of a bank of the memory system;
select a second row of the bank to refresh concurrently with activating the first row of the bank based at least in part on receiving the command;
activate the first row of the bank to transfer charge from a first memory cell to a first sense component of the memory system as part of a host-initiated access operation based at least in part on the command; and
activate the second row of the bank to transfer charge from a second memory cell to a second sense component concurrently with activating the first row as part of a refresh operation based at least in part on selecting the second row.

13. The memory system of claim 12, wherein selecting the second row comprises the processing circuitry configured to cause the memory system to:
determine that the second row is at least a threshold distance away from the first row.

14. The memory system of claim 12, wherein the processing circuitry is further configured to cause the memory system to:
determine a first row index indicated by a refresh counter associated with the bank; and
determine that the first row index is at least a threshold distance away from a second row index of the first row, wherein the second row is selected based at least in part on the first row index being at least the threshold distance away from the second row index of the first row.

15. The memory system of claim 12, wherein the processing circuitry is further configured to cause the memory system to:
determine a first row index indicated by a refresh counter associated with the bank;
determine that the first row index is less than a threshold distance away from a second row index of the first row; and
determine a third row index that is greater than the threshold distance away from the second row index of the first row, wherein the second row is selected based at least in part on the third row index being at least the threshold distance away from the first row index of the first row.

16. The memory system of claim 12, wherein the processing circuitry is further configured to cause the memory system to:
determine a third row to refresh using a refresh counter associated with the bank after activating the second row; and
activate the third row of the bank without activating any other row to refresh the third row.

17. The memory system of claim 12, wherein a first set of refresh operations occur concurrently with host-initiated access operations and a second set of refresh operations occur independently from performing host-initiated access operations.

18. The memory system of claim 12, wherein the memory system attempts refresh operations according to a pattern that interleaves a first set of refresh operations that occur concurrently with host-initiated access operations and a second set of refresh operations that occur independently from performing host-initiated access operations.

19. The memory system of claim 12, wherein the processing circuitry is further configured to cause the memory system to:
determine a first row index indicated by a first refresh counter associated with the bank;
determine a second row index indicated by a second refresh counter associated with the bank; and
determine whether to use the first row index or the second row index as the second row refreshed by the refresh operation, wherein activating the second row is based at least in part on determining whether to use the first row index or the second row index.

20. A non-transitory computer-readable medium storing code, the code comprising instructions executable by one or more processors to:
receive a command to access a first row of a bank of a memory system;
select a second row of the bank to refresh concurrently with activating the first row of the bank based at least in part on receiving the command;
activate the first row of the bank to transfer charge from a first memory cell to a first sense component of the memory system as part of a host-initiated access operation based at least in part on the command; and
activate the second row of the bank to transfer charge from a second memory cell to a second sense component concurrently with activating the first row as part of a refresh operation based at least in part on selecting the second row.
